(19) United States
(12) Patent Application Publication
(10) Pub. No.: US 2026/0082744 A1
(43) Pub. Date: Mar. 19, 2026

(54) TRANSFER SUBSTRATE, METHOD OF MANUFACTURING THE TRANSFER SUBSTRATE, AND WET TRANSFER METHOD FOR SEMICONDUCTOR CHIP

(71) Applicants: SAMSUNG ELECTRONICS CO., LTD., Suwon-si (KR); CHUNGBUK NATIONAL UNIVERSITY INDUSTRY-ACADEMIC COOPERATION FOUNDATION, Cheongju-si (KR)

(72) Inventors: Youngtek OH, Suwon-si (KR); Jaewook JEONG, Cheongju-si (KR); Kyungwook HWANG, Suwon-si (KR); Jinyeong LEE, Cheongju-si (KR); Junsik HWANG, Suwon-si (KR)

(73) Assignees: SAMSUNG ELECTRONICS CO., LTD., Suwon-si (KR); CHUNGBUK NATIONAL UNIVERSITY INDUSTRY-ACADEMIC COOPERATION FOUNDATION, Cheongju-si (KR)

(21) Appl. No.: 19/296,437

(22) Filed: Aug. 11, 2025

(30) Foreign Application Priority Data
Sep. 13, 2024 (KR) 10-2024-0126181

(51) Int. Cl. H10H 29/03; H10H 29/14

(52) U.S. Cl. CPC H10H 29/03; H10H 29/142

(57) ABSTRACT

A transfer substrate includes a base substrate; a guide mold provided on the base substrate and including a plurality of grooves, into which semiconductor chips included in a liquid and supplied to the transfer substrate are to be respectively transferred; and an adhesion auxiliary layer provided on at least one of a surface of the base substrate and a surface of the guide mold, to provide an adhesion force to the semiconductor chips supplied to the transfer substrate, wherein each of the plurality of grooves have a size such that the semiconductor chips having a size of 20 um or less are to be transferred into the plurality of grooves.

### CROSS-REFERENCE TO RELATED APPLICATION

This application is based on and claims priority under 35 U.S.C. § 119 to Korean Patent Application No. 10-2024-0126181, filed on Sep. 13, 2024, in the Korean Intellectual Property Office, the disclosure of which is incorporated by reference herein in its entirety.

### BACKGROUND

### 1. Field

One or more example embodiments of the disclosure relate to a transfer substrate, a method of manufacturing the transfer substrate, and a wet transfer method for a semiconductor chip.

### 2. Description of the Related Art

When a semiconductor chip having a small size is transferred onto a transfer substrate, an adhesion force between the semiconductor chip and the transfer substrate may be small.

With miniaturization of a semiconductor chip, a transfer substrate with an increased transfer efficiency for the semiconductor chip is desirable.

### SUMMARY

One or more example embodiments of the disclosure provide a transfer substrate with high transfer efficiency even for a miniaturized semiconductor chip.

One or more example embodiments of the disclosure provide a method of manufacturing a transfer substrate with an increased transfer efficiency for a miniaturized semiconductor chip.

One or more example embodiments of the disclosure provide a wet transfer method with high transfer efficiency for a semiconductor chip.

Additional aspects will be set forth in part in the description which follows and, in part, will be apparent from the description, or may be learned by practice of the presented embodiments of the disclosure.

According to an aspect of an example embodiment of the disclosure, a transfer substrate includes: a base substrate; a guide mold provided on the base substrate and including a plurality of grooves, into which semiconductor chips included in a liquid and supplied to the transfer substrate are to be respectively transferred; and an adhesion auxiliary layer provided on at least one of a surface of the base substrate and a surface of the guide mold, to provide an adhesion force to the semiconductor chips supplied to the transfer substrate, wherein each of the plurality of grooves have a size such that the semiconductor chips having a size of 20 um or less are to be transferred into the plurality of grooves.

The adhesion auxiliary layer may include at least one of polydimethylsiloxane (PDMS), octadecyltrichlorosilane (OTS), and hexamethyldisilazane (HMDS).

The adhesion auxiliary layer may have a thickness of 100 nm or less.

The adhesion auxiliary layer may be provided on each of the plurality of grooves.

The adhesion auxiliary layer may be provided on the surface of the guide mold.

Bottom surfaces of the plurality of grooves may be plasma-treated.

The adhesion auxiliary layer may be continuously provided on the base substrate and the guide mold.

The guide mold may include a convex pattern formed on an upper surface of the guide mold, and the convex pattern may protrude upwardly.

The convex pattern may include a plurality of convex patterns and may be provided between the plurality of grooves that are adjacent to each other.

The adhesion auxiliary layer may include at least one of chromium (Cr) nanoparticles and titanium (Ti) nanoparticles.

According to an aspect of an example embodiment of the disclosure, a method of manufacturing a transfer substrate includes: preparing a base substrate and a guide mold provided on the base substrate, the guide mold including a plurality of grooves, into which semiconductor chips included in a liquid and supplied to the transfer substrate are to be respectively transferred; arranging a coating material to face the plurality of grooves; and forming an adhesion auxiliary layer by pressing the coating material in a direction toward the plurality of grooves, wherein the adhesion auxiliary layer provides an adhesion force to the semiconductor chips supplied to the transfer substrate.

The coating material may include at least one of polydimethylsiloxane (PDMS), octadecyltrichlorosilane (OTS), and hexamethyldisilazane (HMDS).

The forming of the adhesion auxiliary layer may include forming the adhesion auxiliary layer on the guide mold by pressing the coating material to come into contact with the guide mold.

Bottom surfaces of the plurality of grooves may be plasma-treated.

The forming of the adhesion auxiliary layer may include forming the adhesion auxiliary layer continuously on the base substrate and the guide mold by pressing the coating material to come into contact with the base substrate and the guide mold.

The guide mold may include a convex pattern formed on an upper surface of the guide mold, and the convex pattern may protrude upwardly.

According to an aspect of an example embodiment of the disclosure, a wet transfer method for semiconductor chips includes preparing a transfer substrate having a plurality of grooves; supplying a liquid including semiconductor chips to a surface of the transfer substrate; and aligning the semiconductor chips respectively in the plurality of grooves by sweeping, by a wiper, an upper surface of the transfer substrate to which the liquid including the semiconductor chips is supplied, wherein the transfer substrate includes an adhesion auxiliary layer providing an adhesion force to the semiconductor chips supplied to the surface of the transfer substrate.

The adhesion auxiliary layer may include at least one of polydimethylsiloxane (PDMS), octadecyltrichlorosilane (OTS), and hexamethyldisilazane (HMDS).

The wet transfer method may further include bonding the semiconductor chips respectively transferred into the plurality of grooves onto a drive substrate, and separating the transfer substrate from the drive substrate.

The wet transfer method may further include removing the adhesion auxiliary layer remaining on a bottom surface of at least one semiconductor chip.

### BRIEF DESCRIPTION OF DRAWINGS

The above and other aspects, features, and advantages of certain example embodiments of the disclosure will be more apparent from the following description taken in conjunction with the accompanying drawings, in which:

FIG. 1 is a perspective view of a bare substrate according to an embodiment;

FIG. 2A is a cross-sectional view of a bare substrate according to an embodiment;

FIG. 2B illustrates data obtained by measuring an adhesion force of a semiconductor chip to a bare substrate according to a comparative example;

FIG. 2C illustrates data obtained by measuring an adhesion force of a semiconductor chip to a bare substrate having a plasma-treated surface according to an embodiment;

FIG. 3Aa is a cross-sectional view of a transfer substrate according to an embodiment;

FIG. 3B illustrates data obtained by measuring an adhesion force of a semiconductor chip to a transfer substrate according to an embodiment;

FIG. 4A is a cross-sectional view of a transfer substrate according to an embodiment;

FIG. 4B illustrates data obtained by measuring an adhesion force of a semiconductor chip to a transfer substrate according to an embodiment;

FIG. 5A illustrates data obtained by comparing transfer experimental results for semiconductor chips with each other for the bare substrate and the transfer substrates according to respective embodiments illustrated in FIGS. 2A to 4B;

FIG. 5B is a graph summarizing the experimental results of FIG. 5A;

FIG. 6 is a flowchart illustrating a method of manufacturing a transfer substrate, according to an embodiment;

FIG. 7A is a view illustrating an operation of arranging a coating material according to an embodiment;

FIG. 7B is a view illustrating an operation of forming an adhesion auxiliary layer according to an embodiment;

FIG. 7C is a view illustrating an operation of forming an adhesion auxiliary layer according to an embodiment;

FIG. 8 is a cross-sectional view of a transfer substrate according to an embodiment;

FIG. 9A is a view illustrating an operation of forming an adhesion auxiliary layer according to an embodiment;

FIG. 9B is a view illustrating an operation of forming an adhesion auxiliary layer;

FIG. 10A is a view illustrating an operation of forming an adhesion auxiliary layer according to an embodiment;

FIG. 10B is a view illustrating an operation of forming an adhesion auxiliary layer according to an embodiment;

FIG. 11A is a view illustrating an operation of arranging a coating material according to an embodiment;

FIG. 11B is a view illustrating an operation of forming an adhesion auxiliary layer according to an embodiment;

FIG. 11C is a view illustrating an operation of forming an adhesion auxiliary layer according to an embodiment;

FIG. 12 is a cross-sectional view of a transfer substrate according to an embodiment;

FIG. 13 is a cross-sectional view of a transfer substrate according to an embodiment;

FIG. 14 is an enlarged cross-sectional view of a transfer substrate according to an embodiment;

FIG. 15A is an enlarged cross-sectional view illustrating a shape of a convex pattern, according to an embodiment;

FIG. 15B is an enlarged cross-sectional view illustrating a shape of a convex pattern according to an embodiment;

FIG. 16 is a flowchart illustrating a wet transfer method for a semiconductor chip, according to an embodiment;

FIG. 17A is a view illustrating an operation of supplying a liquid including semiconductor chips onto a surface of a transfer substrate, according to an embodiment;

FIG. 17B is a view illustrating an operation of respectively aligning semiconductor chips in a plurality of grooves, according to an embodiment;

FIG. 17C is a plan view illustrating semiconductor chips respectively aligned in a plurality of grooves of a transfer substrate according to an embodiment;

FIG. 18 is a flowchart illustrating a wet transfer method for a semiconductor chip, according to an embodiment;

FIG. 19A is a cross-sectional view of a transfer structure according to an embodiment;

FIG. 19B is a view illustrating an operation of bonding semiconductor chips onto a drive substrate according to an embodiment;

FIG. 19C is a view illustrating an operation of separating a transfer substrate according to an embodiment;

FIG. 20 is a flowchart illustrating a wet transfer method for a semiconductor chip, according to an embodiment; and

FIG. 21 is a view illustrating an electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described in detail with reference to the accompanying drawings. In the following drawings, the same reference numerals refer to the same components, and a size of each component in the drawings may be exaggerated for the sake of clear and convenient description. In addition, the following embodiments to be described are merely examples, and various modifications may be made from the embodiments. Hereinafter, what is described as “upper portion” or “on or upper” may also include not only components directly thereon, thereunder, on the left, and on the right in contact therewith but also components thereon, thereunder, on the left, and on the right without being in contact therewith. Singular expressions include plural expressions unless the context clearly indicates otherwise. In addition, when a portion “includes” a certain component, this means that other components may be further included rather than excluding other components unless specifically stated to the contrary. Use of a term “the” and similar reference terms may correspond to both the singular and the plural. Steps constituting a method may be performed in any suitable order unless there is a clear statement that the steps should be performed in the order described or contrary to the order and are not limited thereto. In addition, terms such as “ . . . unit”, “ . . . portion”, and “module” described in the specification mean units that process at least one function or operation, which may be implemented as hardware or software, or as a combination of hardware and software. Connection or connection members of lines between configuration elements illustrated in the drawings exemplarily represent functional connections and/or physical or circuit connections and may be represented as alternative or additional various functional connections, physical connections, or circuit connections in an actual apparatus. Use of all examples or all example terms is merely for describing technical ideas in detail, and the scope of claims is not limited by the examples or the example terms unless limited by the claims.

Hereinafter, a transfer substrate, a method of manufacturing the transfer substrate, and a wet transfer method for a semiconductor chip, according to example embodiments, are described in more detail.

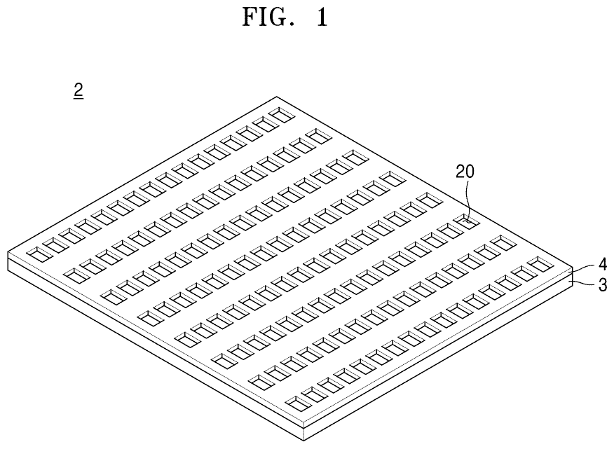

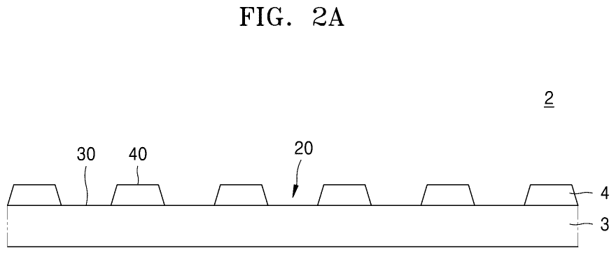

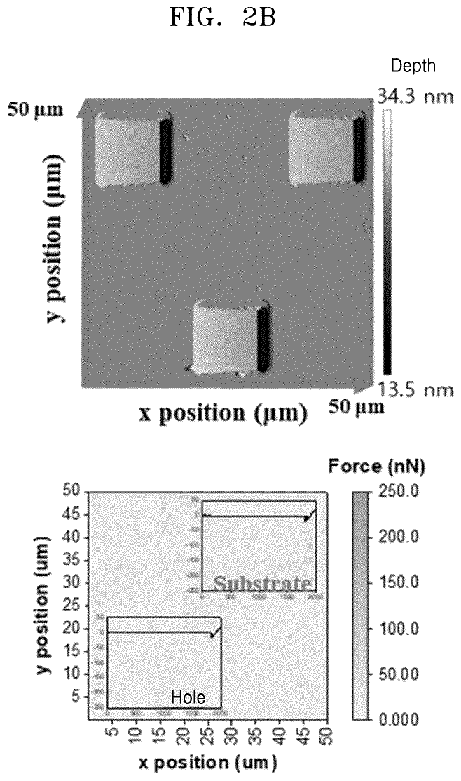

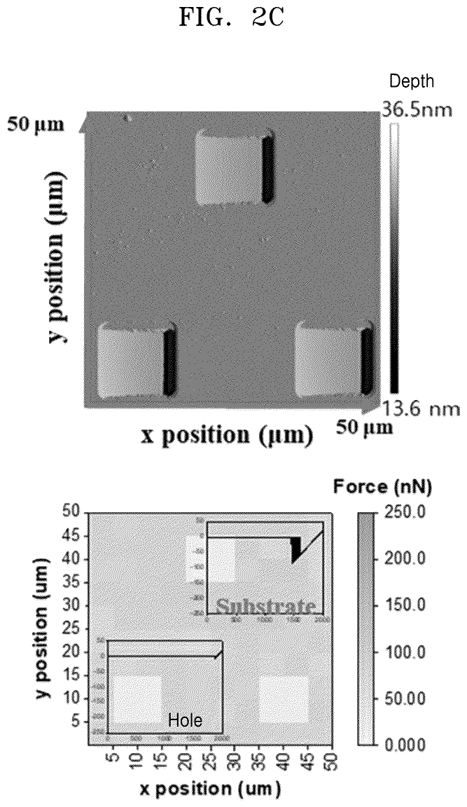

FIG. 1 is a perspective view of a bare substrate 2 according to an embodiment. FIG. 2A is a cross-sectional view of the bare substrate 2 according to the embodiment.

Referring to FIG. 1 and FIG. 2A, the bare substrate 2 according to the embodiment may include a plurality of layers. For example, the bare substrate 2 may include a base substrate 3 and a guide mold 4. The guide mold 4 may be provided on the base substrate 3. The base substrate 3 may serve as a support plate on which the guide mold 4 is provided. A material of the base substrate 3 may be different from a material of the guide mold 4, or may be the same as the material of the guide mold 4. When the material of the base substrate 3 is the same as the material of the guide mold 4, the bare substrate 2 may be configured as a single body.

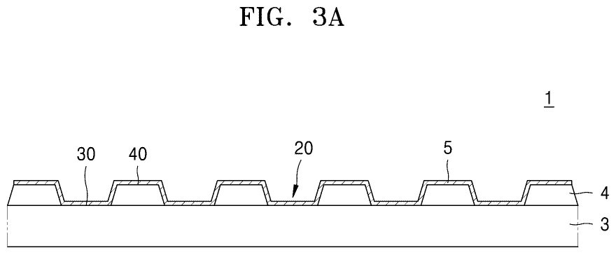

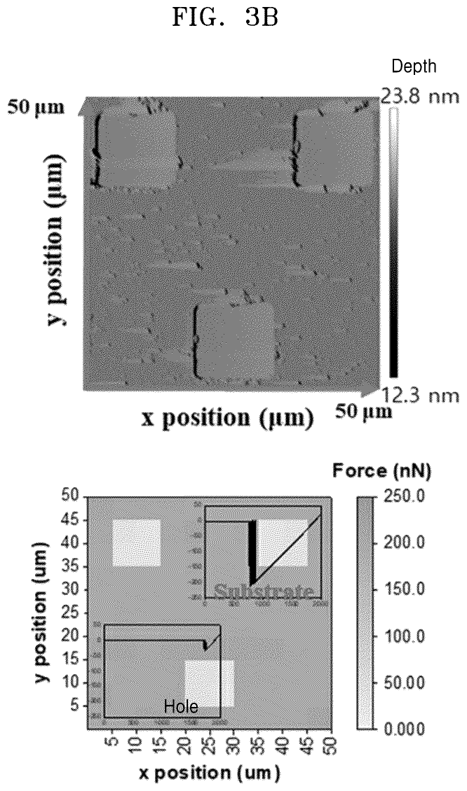

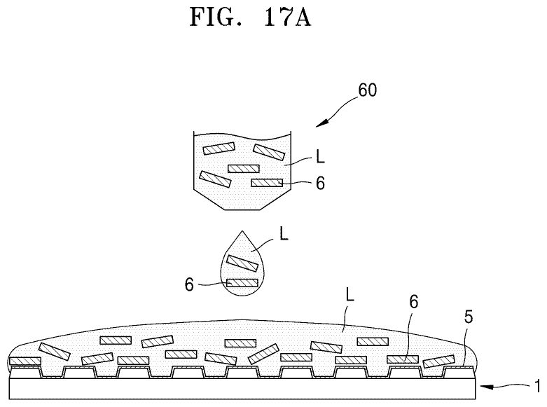

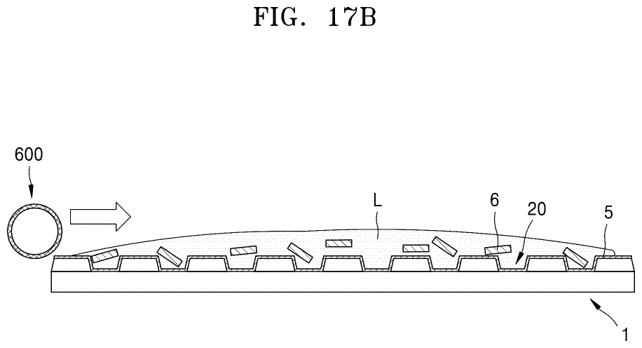

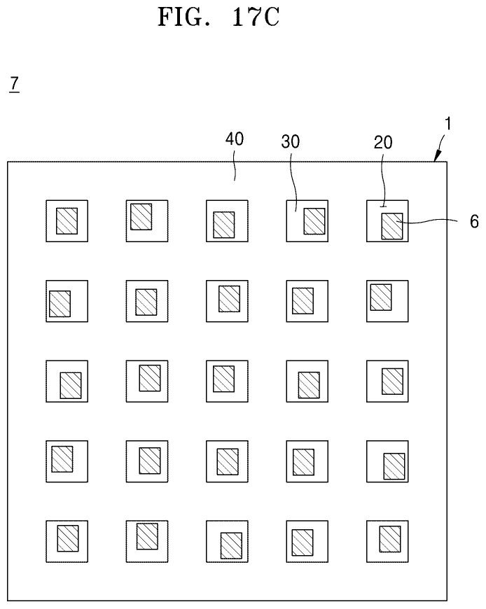

The bare substrate 2 according to an embodiment may include a surface on which an adhesion auxiliary layer 5 (illustrated in FIG. 3A) is provided. When the adhesion auxiliary layer 5 is formed on the bare substrate 2, the adhesion auxiliary layer 5 may be referred to as a transfer substrate 1 (illustrated in FIG. 3A). After the adhesion auxiliary layer 5 is formed on the bare substrate 2, a liquid L (illustrated in FIG. 17A) including semiconductor chips 6 (illustrated in FIG. 17A) may be supplied on the surface of the bare substrate 2. However, the above description is merely an example description and the disclosure is not limited thereto.

An upper surface 40 of the guide mold 4 according to an embodiment may constitute a part of a surface of the bare substrate 2. The guide mold 4 may expose at least a part of the base substrate 3 upwardly in at least some regions excluding the upper surface 40. More specifically, the guide mold 4 may expose at least a part of the base substrate 3 upwardly in at least some inner regions. The base substrate 3 exposed upwardly by the guide mold 4 may be referred to as a bottom surface 30 of the base substrate 3. The bottom surface 30 may constitute a lower surface of a plurality of grooves 20, which will be described later. In other words, the lower surface of the plurality of grooves 20 may also be referred to as the bottom surface 30.

The guide mold 4 according to an embodiment may include the plurality of grooves 20 into which the semiconductor chips 6 are respectively to be transferred. The guide mold 4 may include the plurality of grooves 20 formed in a recessed region of the bare substrate 2. The plurality of grooves 20 may be regions into which the semiconductor chips 6 are respectively to be transferred. Sizes of the plurality of grooves 20 may be according to sizes of the semiconductor chips 6 to be transferred. The sizes of the plurality of grooves 20 may be greater than the sizes of the semiconductor chips 6 to be transferred. For example, the sizes of the plurality of grooves 20 may be about 1.2 times to about 1.3 times the sizes of the semiconductor chips 6. For example, when the size of each of the semiconductor chips 6 is 10 mm, the size of each of the plurality of grooves 20 may be about 12 um to about 13 mm. However, the size described above is only an example, and embodiments are not limited thereto. For example, when a plurality of semiconductor chips 6 are respectively transferred into the plurality of grooves 20, the sizes of the plurality of grooves 20 may be variably determined based on the sizes of the plurality of semiconductor chips 6, for example, at least twice the sizes of the plurality of semiconductor chips 6.

In addition, in order for the semiconductor chips 6 to be transferred well into the plurality of grooves 20, an adhesion force may need to be provided between a surface of the bare substrate 2 or the transfer substrate 1 and the semiconductor chips 6. Here, the adhesion force may be an attractive force acting as a force that attracts each other between the surface of the bare substrate 2 or the transfer substrate 1 and the semiconductor chips 6. Here, the surface of the bare substrate 2 may include the bottom surface 30 of the base substrate 3 and the upper surface 40 of the guide mold 4. Here, a surface of the transfer substrate 1 may include a surface of the adhesion auxiliary layer 5 in addition to the surface of the bare substrate 2. When an adhesive force strongly acts between the surface of the bare substrate 2 or the transfer substrate 1 and the semiconductor chips 6, the semiconductor chips 6 may be well transferred into the plurality of grooves 20.

In addition, the adhesive force acting between the surface of the bare substrate 2 or the transfer substrate 1 and the semiconductor chips 6 may include a Van der Waals force acting between the surface of the bare substrate 2 or the transfer substrate 1 and the semiconductor chips 6. In general, it is known that the Van der Waals force acts more strongly when a mutual contact region between two objects placed opposite each other is larger. In other words, it can be seen that the Van der Waals force acts less strongly when the mutual contact region between two objects placed opposite each other is smaller. For example, when an area of a region of the semiconductor chip 6 that comes into contact with the surface of the bare substrate 2 or the transfer substrate 1 is reduced, the Van der Waals force of the semiconductor chip 6 against the surface of the bare substrate 2 or the transfer substrate 1 may be reduced. In other words, when the area of the region of the semiconductor chip 6 that may come into contact with the bare substrate 2 or the transfer substrate 1 is reduced, an adhesion force of the semiconductor chip 6 to the surface of the bare substrate 2 or the transfer substrate 1 may be reduced. In particular, when a size of the semiconductor chip 6 is reduced by a certain ratio, the adhesion force acting on the semiconductor chip 6 may be reduced by a square of a reduction ratio. For example, when the size of the semiconductor chip 6 is reduced by 1/5 times, the adhesion force acting on the semiconductor chip 6 may be reduced by 1/25 times.

The plurality of grooves 20 of the bare substrate 2 or the transfer substrate 1 according to the embodiment may each include a region onto which the semiconductor chip 6 is to be transferred. Here, a size of the semiconductor chip 6 may be 20 um or less but is not limited thereto, and for example, the size of the semiconductor chip 6 may be 16 um or less. For example, the size of the semiconductor chip 6 may be 10 um or less. For example, the size of the semiconductor chip 6 may be 8 um or less. For example, the size of the semiconductor chip 6 may be 6 um or less.

A surface of the bare substrate 2 or the transfer substrate 1 according to the embodiment may be plasma-treated to increase an adhesion force to the semiconductor chip 6. For example, the upper surface 40 of the guide mold 4 may be plasma-treated to increase the adhesion force acting on the semiconductor chip 6. For example, the bottom surface 30 of the base substrate 3 may be plasma-treated to increase an adhesion force on the semiconductor chip 6.

When a surface of the bare substrate 2 or the transfer substrate 1 according to the embodiment is plasma-treated, roughness of the surface may be reduced. In addition, after the surface of the bare substrate 2 or the transfer substrate 1 is plasma-treated, a hydrophilic material or a hydrophobic material may be applied to the surface of the bare substrate 2 or the transfer substrate 1 to increase an adhesion force on the semiconductor chip 6 but is not limited thereto.

However, the above description is only an example description, and embodiments are not limited thereto.

FIG. 2B illustrates data obtained by measuring an adhesion force of the semiconductor chip 6 to the bare substrate 2 having a surface that is not plasma-treated, according to a comparative example. FIG. 2C illustrates data obtained by measuring an adhesion force of the semiconductor chip 6 to the bare substrate 2 having a plasma-treated surface according to an example embodiment. In this case, a measurement condition for FIGS. 2B and 2C includes measuring an adhesion force of the semiconductor chip 6 having a size of 9 um to each region of the bare substrate 2. In each drawing of FIGS. 2B and 2C, data located on an upper side is data of enlarged portions of the bare substrate 2, and data located on a lower side is atomic force microscopy (AFM) data of an adhesion force of a corresponding region of the bare substrate 2 which acts on the semiconductor chip 6. In the AFM data, a graph denoted by “substrate” shows an adhesion force of the guide mold 4, more specifically, an adhesion force of the upper surface 40 of the guide mold 4 acting on the semiconductor chip 6. In the AFM data, a graph denoted by “hole” shows an adhesion force of the plurality of grooves 20, more specifically, an adhesion force of the bottom surface 30 of the base substrate 3 acting on the semiconductor chip 6.

Referring to FIGS. 2A to 2C, it can be seen that an adhesion force of the bare substrate 2 acting on the semiconductor chip 6 having a size of 9 um is measured to be less in the plurality of grooves 20 than in the guide mold 4. In addition, it can be seen that the adhesion force of the bare substrate 2 having a plasma-treated surface is measured to be greater than an adhesion force of the bare substrate 2 having a surface that is not plasma-treated.

Hereinafter, the adhesion auxiliary layer 5 that provides an adhesion force to the semiconductor chip 6 on a surface will be described. Redundant descriptions thereof will be omitted.

FIG. 3A is a cross-sectional view of a transfer substrate 1 according to an embodiment.

Referring to FIG. 3A, the transfer substrate 1 according to the embodiment may include an adhesion auxiliary layer 5. The adhesion auxiliary layer 5 may be formed on a bare substrate 2 (refer to FIG. 2A). The bare substrate 2 having a surface on which the adhesion auxiliary layer 5 is formed may be referred to as the transfer substrate 1.

The adhesion auxiliary layer 5 according to an embodiment may provide an adhesion force to the semiconductor chip 6 on the surface of the transfer substrate 1. The adhesion auxiliary layer 5 may come into direct contact with the semiconductor chip 6. The adhesion auxiliary layer 5 may provide an adhesion force to the semiconductor chip 6 by increasing the Van der Waals force to the semiconductor chip 6. However, the above description of a function of the adhesion auxiliary layer 5 is merely an example description and the disclosure is not limited thereto.

The adhesion auxiliary layer 5 according to the embodiment may be provided on the bare substrate 2. The adhesion auxiliary layer 5 may be provided on a base substrate 3. More specifically, the adhesion auxiliary layer 5 may be provided on a bottom surface 30 of the base substrate 3. The adhesion auxiliary layer 5 may be provided on a guide mold 4. More specifically, the adhesion auxiliary layer 5 may be provided on an upper surface 40 of the guide mold 4. The adhesion auxiliary layer 5 may be provided on a plurality of grooves 20. The adhesion auxiliary layer 5 provided on the plurality of grooves 20 may mean that the adhesion auxiliary layer 5 is provided on the bottom surface 30 of the base substrate 3, but embodiments are not limited thereto. For example, the adhesion auxiliary layer 5 provided on the plurality of grooves 20 may mean that the adhesion auxiliary layer 5 is provided on the bottom surface 30 of the base substrate 3 in the plurality of grooves 20 and on a side surface of the guide mold 4 in the plurality of grooves 20.

The adhesion auxiliary layer 5 according to the embodiment may be provided continuously on the base substrate 3 and the guide mold 4. More specifically, the adhesion auxiliary layer 5 provided on the base substrate 3 may be connected to the adhesion auxiliary layer 5 provided on the guide mold 4, and thus the adhesion auxiliary layer 5 may be continuously provided. The adhesion auxiliary layer 5 may be continuously provided on a surface of the bare substrate 2. In other words, the adhesion auxiliary layer 5 may cover an entire surface of the bare substrate 2 and may be continuously provided on the bare substrate 2. However, the above description regarding the arrangement and a structure of the adhesion auxiliary layer 5 are merely example descriptions and the disclosure is not limited thereto.

A material of the adhesion auxiliary layer 5 according to the embodiment may include at least one of polydimethylsiloxane (PDMS), octadecyltrichlorosilane (OTS), and hexamethyldisilazane (HMDS). For example, the material of the adhesion auxiliary layer 5 may be polydimethylsiloxane. However, the material of the adhesion auxiliary layer 5 is not limited thereto. For example, the material of the adhesion auxiliary layer 5 may include at least one of chromium (Cr) nanoparticles and titanium (Ti) nanoparticles. In addition, the material of the adhesion auxiliary layer 5 may include various materials that may provide a high adhesion force to the semiconductor chip 6 on the surface of the transfer substrate 1.

FIG. 3B illustrates data obtained by measuring an adhesion force of the semiconductor chip 6 to the transfer substrate 1 according to an embodiment of the disclosure.

Referring to FIG. 2A to FIG. 3B, it can be seen that, when the adhesion auxiliary layer 5 that provides adhesion to the semiconductor chip 6 is formed on a surface of the transfer substrate 1, the adhesion force to the semiconductor chip 6 increases on the surface of the transfer substrate 1. More specifically, it can be seen in the measurement data illustrated in FIG. 3B that an adhesion force of the adhesive auxiliary layer 5 provided on the guide mold 4 acting on the semiconductor chip 6 is greater than an adhesion force of the upper surface 40 of the guide mold 4 on the bare substrate 2 illustrated in FIG. 2B which acts on the semiconductor chip 6, and is greater than an adhesion force of the upper surface 40 of the guide mold 4 on the bare substrate 2 having a plasma-treated surface illustrated in FIG. 2C which acts on the semiconductor chip 6. Also, it can be seen in the measurement data illustrated in FIG. 3B that adhesion force of the plurality of grooves 20, more specifically, an adhesion force of the adhesive auxiliary layer 5 provided on the base substrate 3 which acts on the semiconductor chip 6 is greater than adhesion force of the plurality of grooves 20 on the bare substrate 2 illustrated in FIG. 2B which acts on the semiconductor chip 6, and is greater than an adhesion force of the plurality of grooves 20 on the bare substrate 2 having a plasma-treated surface illustrated in FIG. 2C which acts on the semiconductor chip 6.

When the adhesion auxiliary layer 5 is provided on a surface of a transfer substrate 1 according to an embodiment, an adhesion force may increase between the surface of the transfer substrate 1 and the semiconductor chip 6. When the adhesion force increases between the surface of the transfer substrate 1 and the semiconductor chip 6, a transfer efficiency of the semiconductor chip 6 may be increased. The adhesion auxiliary layer 5 may provide an adhesion force such that the semiconductor chip 6 may be well transferred into the plurality of grooves 20 of the transfer substrate 1. The adhesion auxiliary layer 5 may increase the transfer efficiency of the semiconductor chip 6.

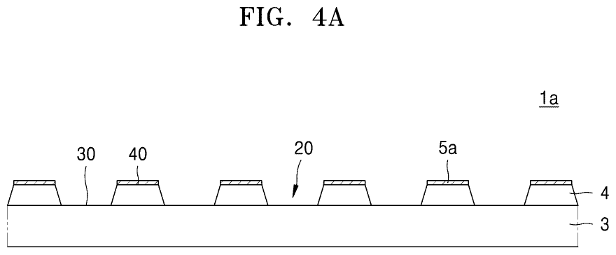

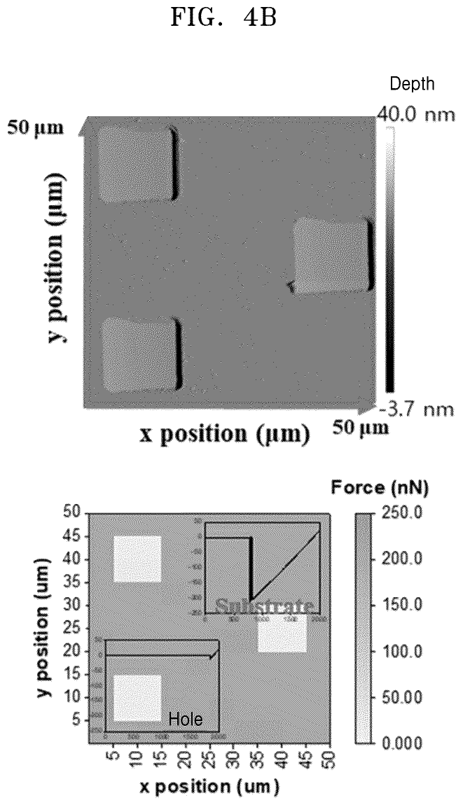

FIG. 4A is a cross-sectional view of a transfer substrate 1a according to an embodiment. The transfer substrate 1a illustrated in FIG. 4A may be different from the transfer substrate 1 illustrated in FIG. 3A.

Referring to FIG. 4A, an adhesion auxiliary layer 5a according to the embodiment may be provided on a guide mold 4. The adhesion auxiliary layer 5a may be provided on an upper surface 40 of the guide mold 4. The adhesion auxiliary layer 5a may be selectively formed on the upper surface 40 of the guide mold 4. The adhesion auxiliary layer 5a may be discontinuously provided on the transfer substrate 1a. In an embodiment, the adhesion auxiliary layer 5a may not be provided on a bottom surface 30 of a base substrate 3. Alternatively, the adhesion auxiliary layer 5a may not be provided on a plurality of grooves 20. However, the description of an arrangement of the adhesion auxiliary layer 5a made above is merely an example description and the disclosure is not limited thereto.

The bottom surface 30 of the base substrate 3 according to the embodiment may be plasma-treated to increase an adhesion force to the semiconductor chip 6. The bottom surfaces 30 of the plurality of grooves 20 may be plasma-treated to increase an adhesion force to the semiconductor chip 6. However, embodiments are not limited to the above description, and for example, an adhesion force to the semiconductor chip 6 may be increased by plasma-treating a side of the guide mold 4 in each of the plurality of grooves 20.

FIG. 4B illustrates data obtained by measuring an adhesion force of the semiconductor chip 6 to the transfer substrate 1a according to an embodiment.

Referring to FIG. 2A to FIG. 2C, FIG. 4A, and FIG. 4B, it can be seen that, when the adhesion auxiliary layer 5a providing an adhesion force to the semiconductor chip 6 is formed on the guide mold 4 according to an embodiment, the adhesion force to the semiconductor chip 6 is increased on a surface of the transfer substrate 1a. More specifically, it can be seen in the measurement data illustrated in FIG. 4B that an adhesion force of the adhesion auxiliary layer 5a provided on the guide mold 4 to the semiconductor chip 6 is greater than an adhesion force of the upper surface 40 of the guide mold 4 on the bare substrate 2 illustrated in FIG. 2B which acts on the semiconductor chip 6, and is greater than an adhesion force of the upper surface 40 of the guide mold 4 on the bare substrate 2 having a plasma-treated surface illustrated in FIG. 2C which acts on the semiconductor chip 6.

When the adhesion auxiliary layer 5a is provided on the guide mold 4 of the transfer substrate 1a according to the embodiment, the adhesive force may increase between a surface of the transfer substrate 1a and the semiconductor chip 6. When an adhesive force increases between the surface of the transfer substrate 1a and the semiconductor chip 6, transfer efficiency of the semiconductor chip 6 may be increased. The adhesion auxiliary layer 5a provided on the guide mold 4 may provide an adhesive force such that the semiconductor chips 6 are well transferred into the plurality of grooves 20 of the transfer substrate 1a. The adhesion auxiliary layer 5a provided on the guide mold 4 may increase the transfer efficiency of the semiconductor chip 6.

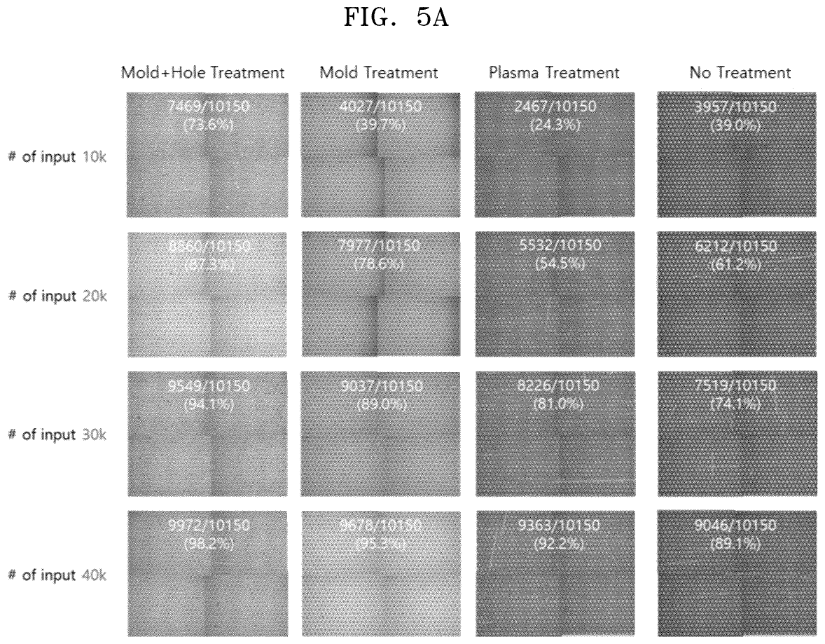

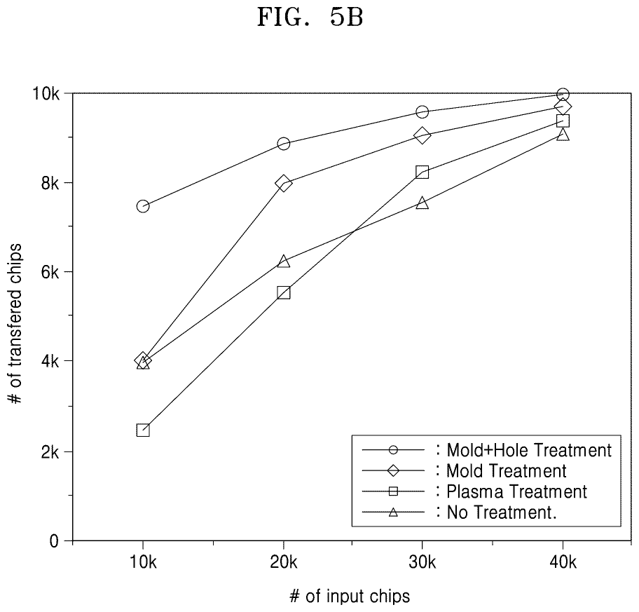

FIG. 5A illustrates data obtained by comparing transfer experimental results for the semiconductor chips 6 with each other for the bare substrate 2 and the transfer substrates 1 and 1a according to respective embodiments illustrated in FIG. 2A to FIG. 4B. FIG. 5B is a graph summarizing the experimental results illustrated in FIG. 5A. In the respective transfer experiments, respective transfer efficiencies were measured by repeatedly performing a process of supplying a liquid L including the semiconductor chips 6 onto surfaces of the bare substrate 2 and the transfer substrates 1 and 1a, scanning the surfaces by a wiper 600, and absorbing the liquid L. In addition, the respective transfer efficiencies were measured by adjusting a number of semiconductor chips 6, which are supplied onto the surfaces of the bare substrate 2 and the transfer substrate 1 and 1a, in units of 10,000.

Referring to FIG. 5A and FIG. 5B, it can be seen that, when the adhesion auxiliary layers 5 and 5a according to embodiments provide an adhesion force to the semiconductor chip 6 on the transfer substrate 1, the transfer efficiencies of the semiconductor chips 6 are increased. In particular, it can be seen that the transfer efficiencies of the semiconductor chips 6 are increased in both the embodiment in which the adhesion auxiliary layer 5 is continuously provided on the base substrate 3 and the guide mold 4 and the embodiment in which the adhesion auxiliary layer 5a is provided only on the guide mold 4. In addition, it can be seen that the transfer efficiency of the semiconductor chips 6 is increased in the embodiment in which a surface of the bare substrate 2 is plasma-treated when the number of semiconductor chips 6 supplied on to the surface of the bare substrate 2 is 30,000 or 40,000.

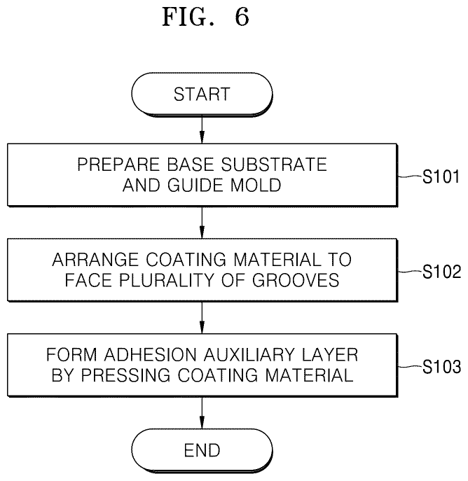

FIG. 6 is a flowchart showing a method of manufacturing the transfer substrate 1, according to an embodiment.

The method of manufacturing the transfer substrate 1 according to the embodiment may be a method of manufacturing the transfer substrate 1 configured to supply the liquid L including the semiconductor chips 6 onto the surfaces of the transfer substrate 1, scan the surfaces by the wiper 600, and absorbing the liquid L. In other words, the method of manufacturing the transfer substrate 1 according to the embodiment may be a method of manufacturing the transfer substrate 1 used for fluidic self assembly (FSA), but the embodiments are not limited thereto.

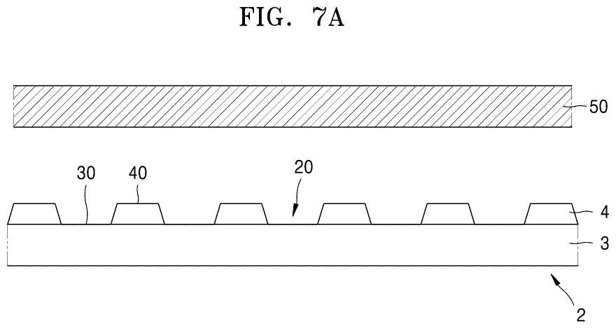

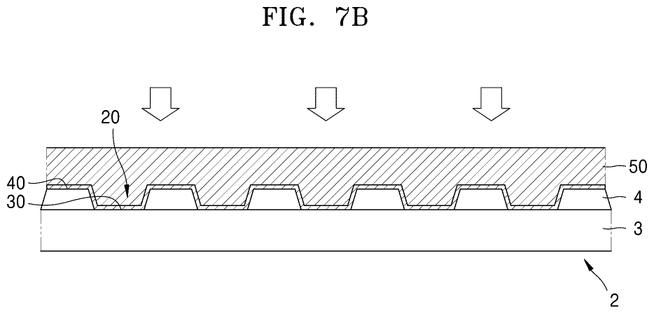

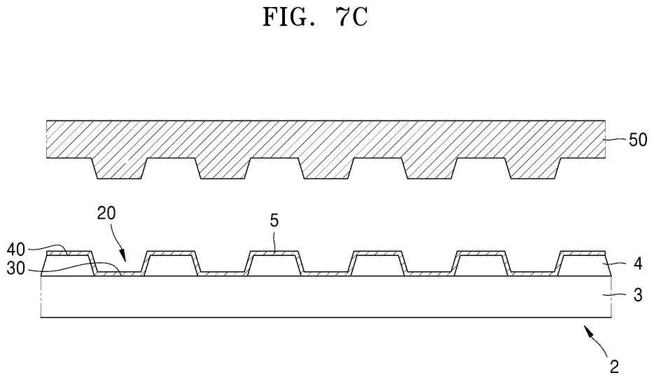

Referring to FIG. 6, the method of manufacturing the transfer substrate 1 according to the embodiment may include an operation S101 of preparing a base substrate and a guide mold, an operation S102 of arranging a coating material 50 (refer to FIG. 7A) to face the plurality of grooves 20, and an operation S103 of forming an adhesion auxiliary layer by pressurizing (or pressing) the coating material 50 against the plurality of grooves 20. The respective operations may be performed in sequence but are not limited thereto. In addition, a separate operation may be added between the respective operations.

The operation S101 of preparing a base substrate and a guide mold according to an embodiment may be an operation of preparing the base substrate 3 and the guide mold 4 wherein a plurality of grooves 20 are provided on the base substrate 3 and into which the semiconductor chips 6 are transferred. In other words, the operation S101 of preparing a base substrate and a guide mold may be an operation of preparing the bare substrate 2 having the plurality of grooves 20. Here, the plurality of grooves 20 may be prepared such that the semiconductor chips 6, each having a size of 20 um or less, are transferred thereinto, but embodiments are not limited thereto.

FIG. 7A is a view illustrating the operation S102 of arranging a coating material, according to an embodiment. FIG. 7B is a view illustrating the operation S103 of forming an adhesion auxiliary layer according to an embodiment. FIG. 7C is a view illustrating the operation S103 of forming an adhesion auxiliary layer according to an embodiment.

Referring to FIG. 6 to FIG. 7C, the operation S102 of arranging a coating material according to the embodiment may be the operation S102 of arranging a coating material to face the bare substrate 2. In this case, the coating material 50 may be provided in parallel to a surface of the bare substrate 2. More specifically, the operation S102 of arranging the coating material may be the operation S102 of arranging a coating material to face the plurality of grooves 20 of the bare substrate 2. A material of the coating material 50 may include at least one of polydimethylsiloxane, octadecyltrichlorosilane, and hexamethyldisilazane but is not limited thereto.

The operation S103 of forming an adhesion auxiliary layer according to an embodiment may be the operation S103 of forming an adhesion auxiliary layer by pressing the coating material 50. In the operation S103 of forming an adhesion auxiliary layer, the coating material 50 may be pressed in a direction facing the plurality of grooves 20 of the bare substrate 2 to be in contact with a surface of the bare substrate 2. In the operation S103 of forming an adhesion auxiliary layer, the coating material 50 may be pressed to be in contact with surfaces of the base substrate 3 and the guide mold 4. More specifically, in the operation S103 of forming an adhesion auxiliary layer, the coating material 50 may be pressed to be in contact with the bottom surface 30 of the base substrate 3 and the upper surface 40 of the guide mold 4. As a result, the transfer substrate 1 according to an embodiment may be provided, as illustrated in FIG. 7C.

In the operation S103 of forming an adhesion auxiliary layer according to an embodiment, a preset pressure applied to the coating material 50 may be, for example, about 0.5 MPa, but is not limited thereto. For example, the adhesion auxiliary layer 5 may also be formed by applying a pressure of about 0.3 MPa to about 1 MPa to the coating material 50. In this case, the time when pressure is applied to the coating material 50 may be 1 to 30 minutes but is not limited thereto. For example, the adhesion auxiliary layer 5 may be formed by applying pressure to the coating material 50 for 30 seconds to 1 hour. Also, the pressure is applied to the coating material under a temperature that may be room temperature but is not limited thereto. For example, the adhesion auxiliary layer 5 may be formed by applying pressure to the coating material 50 while maintaining a temperature range of 25 degrees Celsius to 50 degrees Celsius.

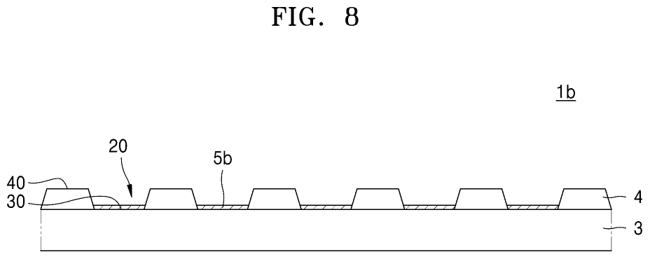

FIG. 8 is a cross-sectional view of a transfer substrate 1b according to an embodiment. The transfer substrate 1b illustrated in FIG. 8 may be different from the transfer substrates 1 and 1a illustrated in FIG. 3A and FIG. 4A.

Referring to FIG. 8, an adhesion auxiliary layer 5b of the transfer substrate 1b according to the embodiment may be provided on a plurality of grooves 20. The adhesion auxiliary layer 5b may be provided on the base substrate 3. The adhesion auxiliary layer 5b may be provided on a bottom surface 30 of the base substrate 3. In other words, the adhesion auxiliary layer 5b may be provided on the bottom surfaces 30 of the plurality of grooves 20. The bottom surface 30 of the base substrate 3 may be understood as the bottom surfaces 30 of the plurality of grooves 20. The adhesion auxiliary layer 5b may be selectively formed on the bottom surface 30 of the base substrate 3. The adhesion auxiliary layer 5b may be discontinuously provided on the transfer substrate 1b. In other words, the adhesion auxiliary layer 5b may not be provided on an upper surface 40 of a guide mold 4. However, the above description of an arrangement of the adhesion auxiliary layer 5b is merely an example description and the disclosure is not limited thereto.

Referring again to FIG. 6 to FIG. 8, after forming the adhesion auxiliary layer 5 on the transfer substrate 1 according to the embodiment, at least a part of the adhesion auxiliary layer 5 may be removed. More specifically, by removing at least a part of the adhesion auxiliary layer 5 from the transfer substrate 1 illustrated in FIG. 7C, the transfer substrate 1b illustrated in FIG. 8 may be provided. At least a part of the adhesion auxiliary layer 5 may be removed through a selective etching process but is not limited thereto. Also, the method of manufacturing the transfer substrate 1b illustrated in FIG. 8 is not limited to the above description. For example, in the operation S103 of forming an adhesion auxiliary layer by pressing the coating material 50, the transfer substrate 1b illustrated in FIG. 8 may also be manufactured by pressing the coating material 50 to selectively come into contact with the plurality of grooves 20 to form the adhesion auxiliary layer 5b.

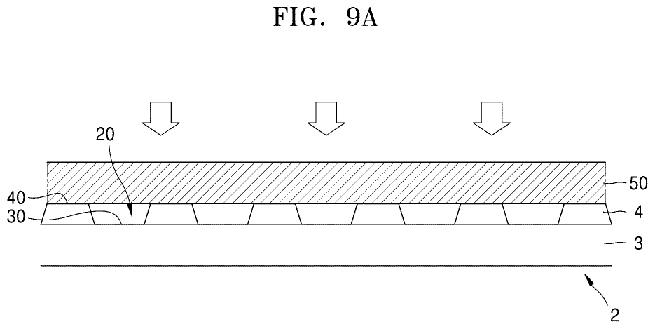

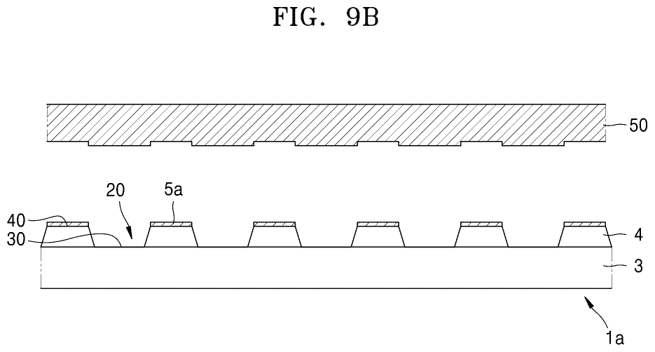

FIG. 9A is a view illustrating the operation S103 of forming an adhesion auxiliary layer, according to an embodiment. FIG. 9B is a view illustrating the operation S103 of forming an adhesion auxiliary layer, according to an embodiment. The operation S103 of forming the adhesion auxiliary layer illustrated in FIG. 9A and FIG. 9B may be different from the operation S103 of forming the adhesion auxiliary layer described with reference to FIG. 7B and FIG. 7C. More specifically, the operation S103 of forming the adhesion auxiliary layer illustrated in FIG. 9A and FIG. 9B may be a part of the method of manufacturing the transfer substrate 1a illustrated in FIG. 4A. Hereinafter, redundant descriptions thereof will be omitted, and differences therebetween are mainly described.

Referring to FIG. 6, FIG. 9A, and FIG. 9B, in the operation S103 of forming an adhesion auxiliary layer according to an embodiment, the coating material 50 may come into contact with a surface of the guide mold 4 by applying pressure thereto. More specifically, in the operation S103 of forming an adhesion auxiliary layer, the coating material 50 may come into contact with the upper surface 40 of the guide mold 4 by applying pressure thereto. In the operation S103 of forming an adhesion auxiliary layer, the adhesion auxiliary layer 5a may be selectively formed on the upper surface 40 of the guide mold 4 by causing the coating material 50 to come into contact with the upper surface 40 of the guide mold 4. In this case, the coating material 50 may be in soft contact with the upper surface 40 of the guide mold 4. The adhesion auxiliary layer 5a may be formed in plural on respective guide molds 4.

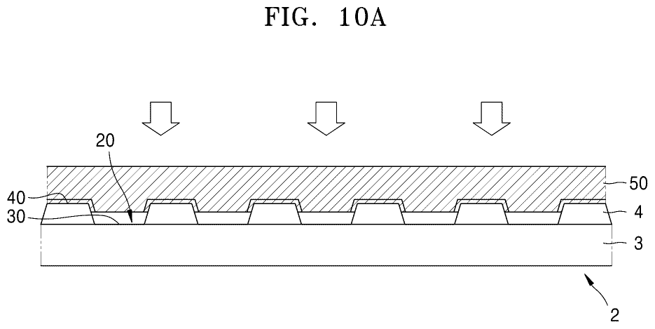

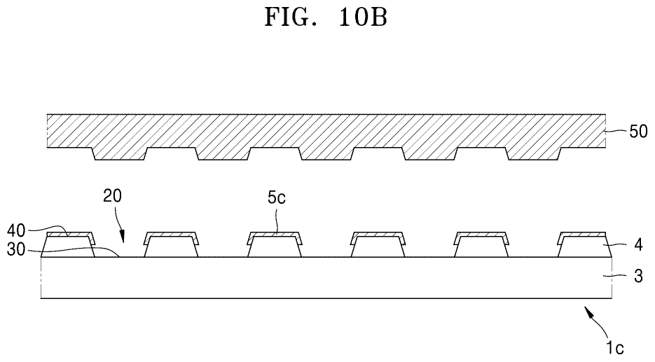

FIG. 10A is a view illustrating the operation S103 of forming an adhesion auxiliary layer, according to an embodiment. FIG. 10B is a view illustrating the operation S103 of forming an adhesion auxiliary layer according to an embodiment.

The operation S103 of forming the adhesion auxiliary layer illustrated in FIG. 10A and FIG. 10B may be different from the operation S103 of forming the adhesion auxiliary layer described with reference to FIG. 7B to FIG. 8B. Hereinafter, redundant descriptions thereof are omitted, and differences therebetween are mainly described.

Referring to FIG. 6, FIG. 10A, and FIG. 10B, in the operation S103 of forming an adhesion auxiliary layer according to an embodiment, the coating material 50 may come into contact with a surface and a side surface of the guide mold 4 by applying pressure thereto. In the operation S103 of forming an adhesion auxiliary layer, the coating material 50 may come into contact with the upper surface 40 of the guide mold 4 and the side surfaces in the plurality of grooves 20 by applying pressure thereto. In the operation S103 of forming an adhesion auxiliary layer, an adhesion auxiliary layer 5c may be selectively formed on the upper surface 40 and a side surface of the guide mold 4 by pressing the coating material 50 to come into contact with the upper surface 40 and the side surface of the guide mold 4 and applying pressure thereto.

A transfer substrate 1c according to an embodiment may include the adhesion auxiliary layer 5c selectively formed on the upper surface 40 and the side surface of the guide mold 4. A plurality of adhesion auxiliary layers 5c may be respectively formed on the guide molds 4. The plurality of adhesion auxiliary layers 5c may respectively surround upper surfaces 40 of the guide molds 4. The plurality of adhesion auxiliary layers 5c may each have a roughly cap shape on the guide mold 4 but is not limited thereto.

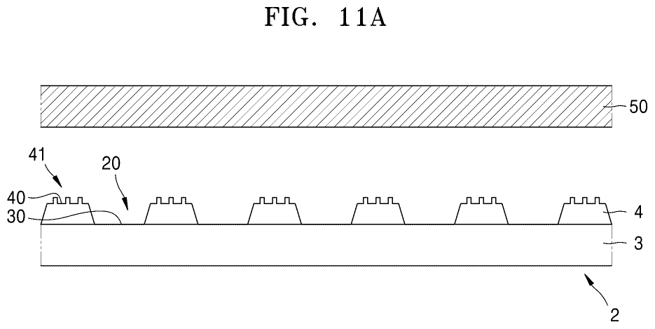

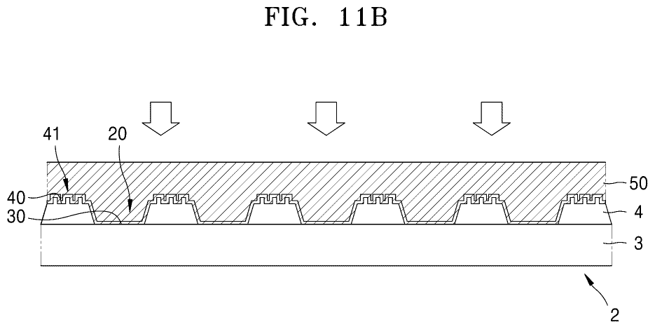

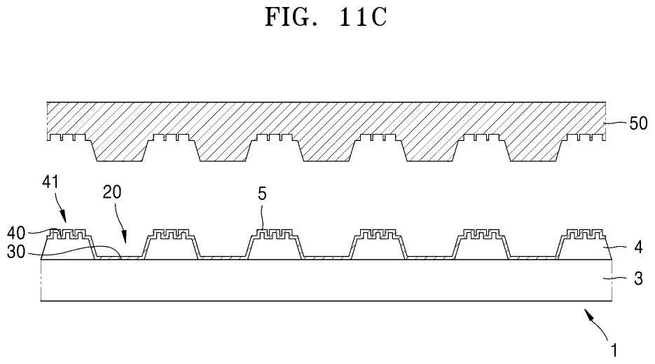

FIG. 11A is a view illustrating the operation (S102) of arranging a coating material, according to an embodiment. FIG. 11B is a view illustrating the operation S103 of forming an adhesion auxiliary layer according to an embodiment. FIG. 11C is a view illustrating the operation S103 of forming an adhesion auxiliary layer according to an embodiment. Views illustrated in FIG. 11A to FIG. 11C may be substantially the same as the views illustrated in FIG. 7A to FIG. 7C except for a convex pattern 41. Hereinafter, redundant descriptions thereof are omitted, and differences therebetween are mainly described.

Referring to FIG. 11A to FIG. 11C, a bare substrate 2 according to an embodiment may include the convex pattern 41. A transfer substrate 1 may include the convex pattern 41. A guide mold 4 may include the convex pattern 41 formed on an upper surface 40 of the guide mold 4. When an adhesion auxiliary layer 5 is formed on the guide mold 4 on which the convex pattern 41 is formed, the adhesion auxiliary layer 5 may be formed to follow a surface of the convex pattern 41 on the convex pattern 41. In other words, the adhesion auxiliary layer 5 formed on the convex pattern 41 of the guide mold 4 may also be referred to as the convex pattern 41.

The convex pattern 41 according to an embodiment may protrude upwardly on a surface of the bare substrate 2 or the transfer substrate 1 such that semiconductor chips 6 may respectively and easily move into the plurality of grooves 20. The convex pattern 41 may reduce surface energy of the upper surface 40 of the guide mold 4. The convex pattern 41 may prevent the semiconductor chip 6 from being fixed on the upper surface 40 of the guide mold 4. In other words, the convex pattern 41 may reduce energy of the upper surface 40 of the guide mold 4 such that the semiconductor chips 6 may respectively slide toward the plurality of grooves 20 on the upper surface 40 of the guide mold 4. The convex pattern 41 may reduce the energy of the upper surface 40 of the guide mold 4 such that the semiconductor chip 6 may be easily transferred into each of the plurality of grooves 20 on the transfer substrate 1. However, a function of the convex pattern 41 is not limited to the above description, and a specific shape and arrangement of the convex pattern 41 is described below.

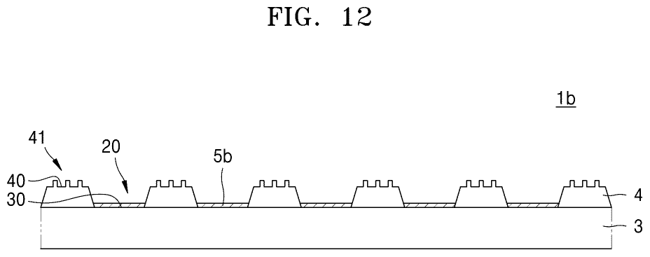

FIG. 12 is a cross-sectional view of a transfer substrate 1b according to an embodiment. The transfer substrate 1b illustrated in FIG. 12 may be substantially the same as the transfer substrate 1b illustrated in FIG. 8, except for the convex pattern 41.

Referring to FIG. 12, the transfer substrate 1b according to an embodiment may have an adhesion auxiliary layer 5b provided on each of a plurality of grooves 20. In this case, the convex pattern 41 may be provided on an upper surface 40 of a guide mold 4. The convex pattern 41 may reduce the energy of the upper surface 40 of the guide mold 4 such that a semiconductor chip 6 may be easily transferred into each of the plurality of grooves 20. The adhesion auxiliary layer 5b may provide an adhesive force to the semiconductor chips 6 such that the semiconductor chip 6 may be easily transferred into each of the plurality of grooves 20.

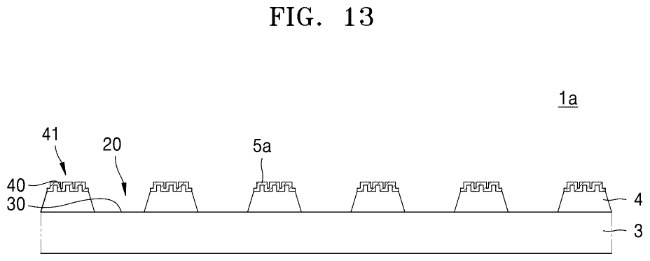

FIG. 13 is a cross-sectional view of a transfer substrate 1a according to an embodiment. The transfer substrate 1a illustrated in FIG. 13 may be substantially the same as the transfer substrate 1a illustrated in FIG. 4A, except for a convex pattern 41.

Referring to FIG. 13, the transfer substrate 1a according to the embodiment may have an adhesion auxiliary layer 5a provided on the guide mold 4. In this case, the convex pattern 41 may be provided on an upper surface 40 of the guide mold 4. The convex pattern 41 may reduce the energy of the upper surface 40 of the guide mold 4 such that a semiconductor chip 6 may be easily transferred into each of the plurality of grooves 20. The adhesion auxiliary layer 5a may provide an adhesive force to the semiconductor chip 6 such that the semiconductor chip 6 may be easily transferred into each of the plurality of grooves 20.

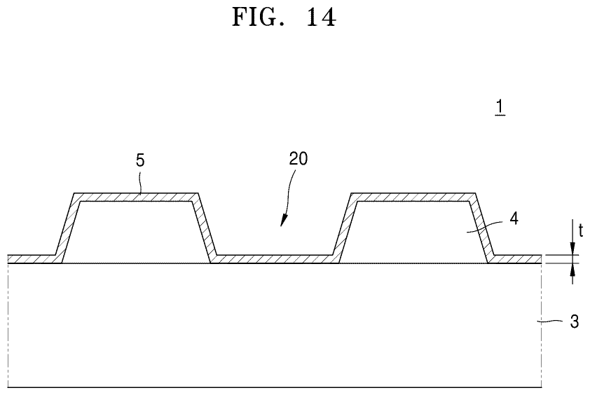

FIG. 14 is an enlarged cross-sectional view of a transfer substrate 1 according to an embodiment.

Referring to FIG. 14, an adhesion auxiliary layer 5 according to an embodiment may be formed along a surface of the transfer substrate 1 and have a preset thickness t. The thickness t of the adhesion auxiliary layer 5 may be 100 nm or less but is not limited thereto. For example, the thickness t of the adhesion auxiliary layer 5 may be about 10 nm to about 200 nm. The thickness t of the adhesion auxiliary layer 5 may be about 50 nm to about 150 nm.

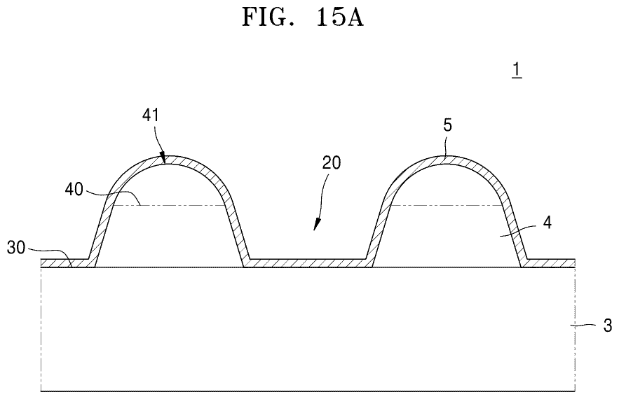

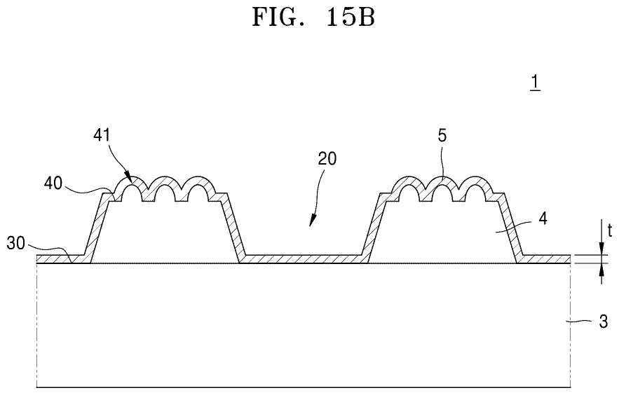

FIG. 15A is an enlarged cross-sectional view illustrating a shape of a convex pattern 41 according to an embodiment. FIG. 15B is an enlarged cross-sectional view illustrating a shape of a convex pattern 41 according to an embodiment.

Referring again to FIG. 11C to FIG. 13, FIG. 15A, and FIG. 15B, the convex pattern 41 according to the embodiment may be formed as a single pattern or multiple patterns on the upper surface 40 of the guide mold 4. When there are multiple convex patterns 41, the number of convex patterns 41 provided between adjacent multiple grooves 20 may be about 2 to 100. However, the above description of the number of convex patterns 41 is merely an example description and the disclosure is not limited thereto.

When there are multiple convex patterns 41 according to an embodiment, an interval between the multiple convex patterns 41 may be set such that the semiconductor chip 6 is not fixed on the multiple convex patterns 41. In other words, the interval between the multiple convex patterns 41 may be set such that the movement of the semiconductor chip 6 is not hindered by a well formed between the adjacent convex patterns 41.

A cross-sectional shape of the convex pattern 41 according to the embodiment may have a semicircular shape, but is not limited thereto, and may be changed to any one of various polygonal shapes such as, for example, an oval or a rectangle.

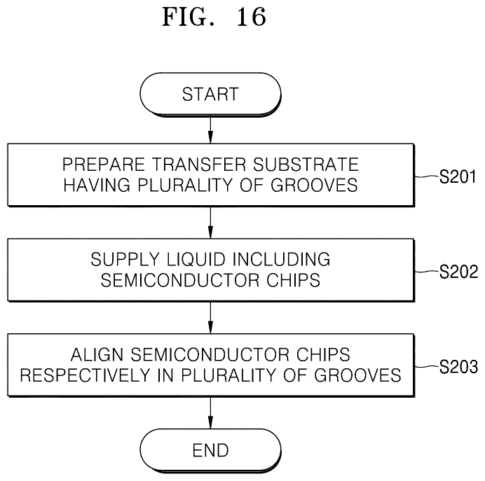

FIG. 16 is a flowchart illustrating a wet transfer method for the semiconductor chips 6, according to an embodiment.

Referring to FIG. 16, the wet transfer method for the semiconductor chips 6, according to the embodiment, may include a method of wetly transferring the semiconductor chips 6 respectively into the transfer substrate 1 having the plurality of grooves 20. The wet transfer method for the semiconductor chips 6 may include an operation S201 of preparing a transfer substrate having a plurality of grooves, an operation S202 of supplying a liquid including the semiconductor chips 6 onto a surface of the transfer substrate 1, and an operation S203 of respectively aligning the semiconductor chips 6 in the plurality of grooves by using the wiper 600 to sweep the upper surface 40 of the transfer substrate 1 including the liquid L. Respective operations may be performed in sequence but are not limited thereto. Also, a separate operation may be added between the respective operations.

The operation S201 of preparing a transfer substrate having a plurality of grooves, according to an embodiment, may be an operation of preparing the transfer substrate 1 which has the plurality of grooves 20 and includes the adhesion auxiliary layer 5 providing an adhesive force to the semiconductor chips 6.

FIG. 17A is a view illustrating the operation S202 of supplying a liquid including the semiconductor chips 6 on a surface of the transfer substrate 1 according to an embodiment.

Referring to FIG. 16 and FIG. 17A, in the operation S202 of supplying a liquid including the semiconductor chips 6 onto the transfer substrate 1 according to an embodiment, a liquid supply unit 60 may supply a liquid L including the semiconductor chips 6 onto a surface of the transfer substrate 1. The liquid supply unit 60 may supply the liquid L including a plurality of semiconductor chips 6 on the surface of the transfer substrate 1. In this case, any of various methods, such as a spray method, a dispensing method, an inkjet dot method, and so on may be used as a method of supplying the liquid L may include, but embodiments are not limited thereto.

FIG. 17B is a view illustrating the operation S203 of respectively aligning the semiconductor chips 6 in a plurality of grooves, according to an embodiment. FIG. 17C is a plan view showing the semiconductor chips 6 respectively aligned in the plurality of grooves 20 of the transfer substrate 1 according to an embodiment.

Referring to FIG. 16 to FIG. 17C, in the operation S203 of respectively aligning the semiconductor chips 6 in the plurality of grooves 20 by sweeping, by the wiper 600 according to an embodiment, the upper surface 40 of the transfer substrate 1 including the liquid L, the wiper 600 may move along the surface of the transfer substrate 1. The wiper 600 may move along the surface of the transfer substrate 1 while in contact with the surface of the transfer substrate 1. The wiper 600 may include an absorbent structure capable of absorbing the liquid L. The wiper 600 may absorb the liquid L by sweeping the upper surface 40 of the transfer substrate 1. As the wiper 600 sweeps the upper surface 40 of the transfer substrate 1 and absorb the liquid L, the semiconductor chips 6 may be respectively aligned in the plurality of grooves 20. However, the above description is merely an example description and the disclosure is not limited thereto.

A structure, in which the semiconductor chips 6 are respectively transferred into the plurality of grooves 20 of the transfer substrate 1 according to an embodiment, may be referred to as a transfer structure 7, as illustrated in FIG. 17C.

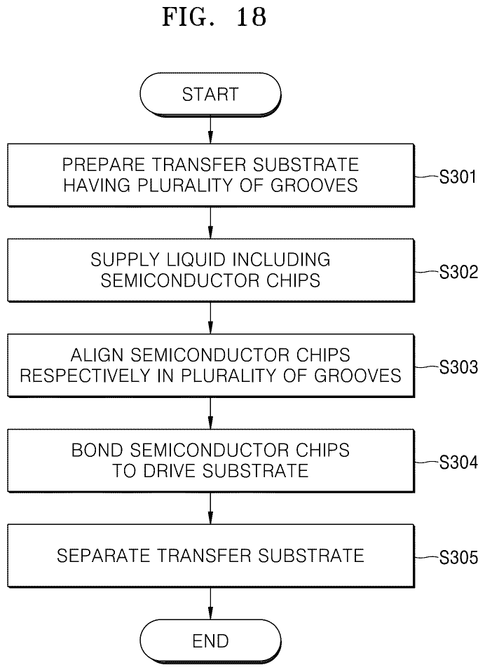

FIG. 18 is a flowchart illustrating a wet transfer method for the semiconductor chip 6, according to an embodiment.

Referring to FIG. 18, the wet transfer method for the semiconductor chip 6, according to the embodiment, may further include an operation S304 of bonding the semiconductor chip 6 onto a drive substrate and an operation S305 of separating a transfer substrate.

The operation S304 of bonding the semiconductor chip 6 onto a drive substrate, according to an embodiment, may be performed after the operation S303 of respectively aligning the semiconductor chips 6 in a plurality of grooves but is not limited thereto.

The operation S305 of separating a transfer substrate, according to the embodiment, may be performed after the operation S304 of bonding the semiconductor chip 6 onto a drive substrate but is not limited thereto.

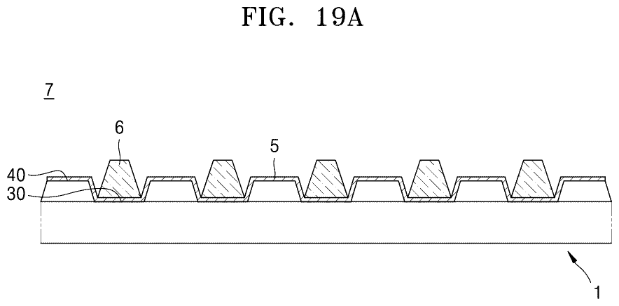

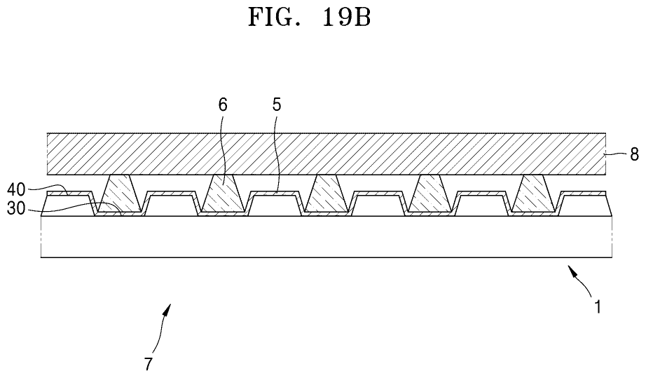

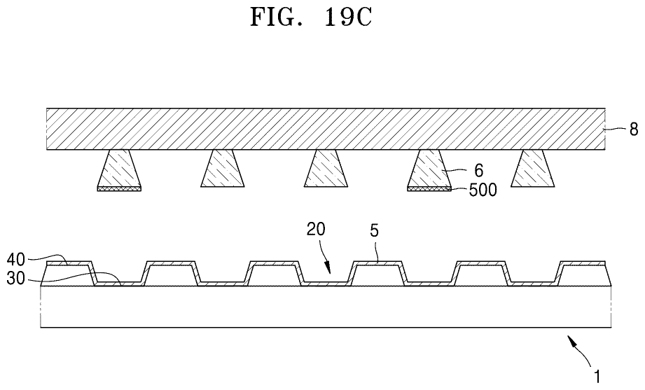

FIG. 19A is a cross-sectional view of a transfer structure 7 according to an embodiment. FIG. 19B is a view illustrating the operation (S304) of bonding the semiconductor chips 6 onto a drive substrate according to an embodiment. FIG. 19C is a view illustrating the operation S305 of separating a transfer substrate according to an embodiment.

Referring to FIG. 18 to FIG. 19C, the operation S304 of bonding the semiconductor chips 6 onto a drive substrate, according to the embodiment, may be the operation S304 of bonding the semiconductor chips 6 respectively transferred into the plurality of grooves 20 onto the drive substrate. In other words, the semiconductor chips 6 may be bonded onto a drive substrate 8 by arranging the drive substrate 8 on the transfer structure 7 to face the semiconductor chips 6. Here, bonding the semiconductor chips 6 to the drive substrate 8 may include electrically connecting respective semiconductor chips 6 to the drive substrate 8.

In the operation S305 of separating the transfer substrate, according to the embodiment, the transfer substrate 1 may be separated from the semiconductor chips 6 by separating the transfer substrate 1 from the drive substrate 8. In the operation S305 of separating the transfer substrate 1, the adhesion auxiliary layer 5 may be separated from the semiconductor chips 6.

In addition, in the operation S305 of separating the transfer substrate, at least a part of the adhesion auxiliary layer 5 may not be separated from a bottom surface of the semiconductor chip 6. In other words, at least a part of the adhesion auxiliary layer may remain on the bottom surface of the semiconductor chip 6 in the operation of separating the transfer substrate S305, as illustrated in FIG. 19C.

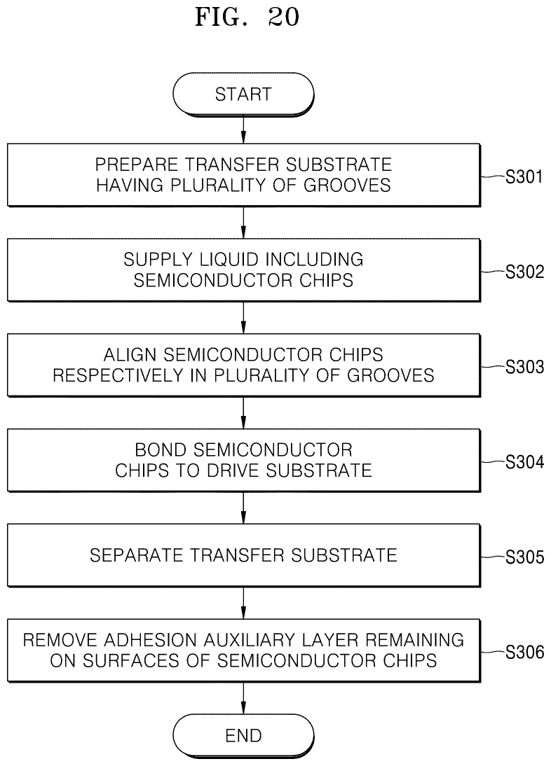

FIG. 20 is a flowchart illustrating a wet transfer method for the semiconductor chip 6 according to an embodiment.

Referring to FIG. 20, the wet transfer method for the semiconductor chip 6, according to an embodiment, may further include an operation S306 of removing an adhesion auxiliary layer remaining on a bottom surface of the semiconductor chip 6.

The operation S306 of removing the adhesion auxiliary layer remaining on the bottom surface of the semiconductor chip 6, according to an embodiment, may be performed after the operation S305 of separating a transfer substrate but is not limited thereto.

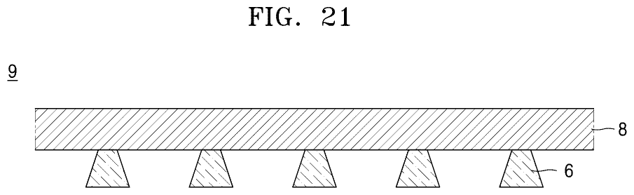

FIG. 21 is a view illustrating an electronic device 9 according to an embodiment.

Referring to FIG. 20 and FIG. 21, when the adhesion auxiliary layer 5, which remains on a bottom surface of the semiconductor chip 6 bonded to a drive substrate 8, is removed, the drive substrate 8 and the semiconductor chip 6 may be referred to as the electronic device 9. However, the disclosure is not limited thereto, and for example, even when the adhesion auxiliary layer 5 does not remain on the bottom surface of the semiconductor chip 6 after the operation S305 of separating a transfer substrate, the drive substrate 8 and the semiconductor chip 6 bonded to the drive substrate 8 may be referred to as the electronic device 9.

In the wet transfer method for the semiconductor chip 6, according to the embodiment, the electronic device 9 may be provided through the operation S306 of removing an adhesion auxiliary layer remaining on a bottom surface of the semiconductor chip 6. In this case, the semiconductor chip 6 may be a light emitting diode (LED) including a micro LED but is not limited thereto. For example, when the semiconductor chip 6 is a micro LED, the electronic device 9 may be a display device but is not limited thereto.

An embodiment may provide a transfer substrate including an adhesion auxiliary layer that provides an adhesion force to a semiconductor chip.

Another embodiment may provide a method of manufacturing a transfer substrate with a high adhesion force to a semiconductor chip.

Another embodiment may provide a wet transfer method for a semiconductor chip with high transfer efficiency to the semiconductor chip.

The above-described embodiments are merely examples, and those skilled in the art may make various modifications and derive equivalent other embodiments from the embodiments. Therefore, the true technical protection scope according to the present embodiments should be determined by the technical idea described in the following patent claims and their equivalents.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A transfer substrate comprising:
a base substrate;
a guide mold provided on the base substrate and including a plurality of grooves, into which semiconductor chips included in a liquid and supplied to the transfer substrate are to be respectively transferred; and
an adhesion auxiliary layer provided on at least one of a surface of the base substrate and a surface of the guide mold, to provide an adhesion force to the semiconductor chips supplied to the transfer substrate,
wherein each of the plurality of grooves have a size such that the semiconductor chips having a size of 20 um or less are to be transferred into the plurality of grooves.

2. The transfer substrate of claim 1, wherein the adhesion auxiliary layer includes at least one of polydimethylsiloxane (PDMS), octadecyltrichlorosilane (OTS), and hexamethyldisilazane (HMDS).

3. The transfer substrate of claim 2, wherein the adhesion auxiliary layer has a thickness of 100 nm or less.

4. The transfer substrate of claim 3, wherein the adhesion auxiliary layer is provided on each of the plurality of grooves.

5. The transfer substrate of claim 3, wherein the adhesion auxiliary layer is provided on the surface of the guide mold.

6. The transfer substrate of claim 5, wherein bottom surfaces of the plurality of grooves are plasma-treated.

7. The transfer substrate of claim 3, wherein the adhesion auxiliary layer is continuously provided on the base substrate and the guide mold.

8. The transfer substrate of claim 3, wherein the guide mold includes a convex pattern formed on an upper surface of the guide mold, and
wherein the convex pattern protrudes upwardly.

9. The transfer substrate of claim 8, wherein the convex pattern includes a plurality of convex patterns and is provided between the plurality of grooves that are adjacent to each other.

10. The transfer substrate of claim 1, wherein the adhesion auxiliary layer includes at least one of chromium (Cr) nanoparticles and titanium (Ti) nanoparticles.

11. A method of manufacturing a transfer substrate, the method comprising:
preparing a base substrate and a guide mold provided on the base substrate, the guide mold including a plurality of grooves, into which semiconductor chips included in a liquid and supplied to the transfer substrate are to be respectively transferred;
arranging a coating material to face the plurality of grooves; and
forming an adhesion auxiliary layer by pressing the coating material in a direction toward the plurality of grooves, wherein the adhesion auxiliary layer provides an adhesion force to the semiconductor chips supplied to the transfer substrate.

12. The method of claim 11, wherein the coating material includes at least one of polydimethylsiloxane (PDMS), octadecyltrichlorosilane (OTS), and hexamethyldisilazane (HMDS).

13. The method of claim 12, wherein the forming the adhesion auxiliary layer comprises forming the adhesion auxiliary layer on the guide mold by pressing the coating material to come into contact with the guide mold.

14. The method of claim 13, wherein bottom surfaces of the plurality of grooves are plasma-treated.

15. The method of claim 12, wherein the forming the adhesion auxiliary layer comprises forming the adhesion auxiliary layer continuously on the base substrate and the guide mold by pressing the coating material to come into contact with the base substrate and the guide mold.

16. The method of claim 13, wherein the guide mold includes a convex pattern formed on an upper surface of the guide mold, and
wherein the convex pattern protrudes upwardly.

17. A wet transfer method for semiconductor chips, the wet transfer method comprising:
preparing a transfer substrate having a plurality of grooves;
supplying a liquid including semiconductor chips to a surface of the transfer substrate; and
aligning the semiconductor chips respectively in the plurality of grooves by sweeping, by a wiper, an upper surface of the transfer substrate to which the liquid including the semiconductor chips is supplied,
wherein the transfer substrate includes an adhesion auxiliary layer providing an adhesion force to the semiconductor chips supplied to the surface of the transfer substrate.

18. The wet transfer method of claim 17, wherein the adhesion auxiliary layer includes at least one of polydimethylsiloxane (PDMS), octadecyltrichlorosilane (OTS), and hexamethyldisilazane (HMDS).

19. The wet transfer method of claim 18, further comprising:
bonding the semiconductor chips, respectively transferred into the plurality of grooves, onto a drive substrate; and
separating the transfer substrate from the drive substrate.

20. The wet transfer method of claim 19, further comprising removing the adhesion auxiliary layer remaining on a bottom surface of at least one semiconductor chip.
